(19) United States
(12) Patent Application Publication
(10) Pub. No.: US 2013/0027885 A1
(43) Pub. Date: Jan. 31, 2013

(54) HEAT SPREADER FOR MULTI-CHIP MODULES

(71) Applicants: David L. Edwards, Poughkeepsie, NY (US); Randall G. Kemink, Poughkeepsie, NY (US); David C. Olson, Lagrangeville, NY (US); Michael T. Peets, Staatsburg, NY (US); John G. Torok, Poughkeepsie, NY (US); Wade H. White, Hyde Park, NY (US)

(72) Inventors: David L. Edwards, Poughkeepsie, NY (US); Randall G. Kemink, Poughkeepsie, NY (US); David C. Olson, Lagrangeville, NY (US); Michael T. Peets, Staatsburg, NY (US); John G. Torok, Poughkeepsie, NY (US); Wade H. White, Hyde Park, NY (US)

(73) Assignee: INTERNATIONAL BUSINESS MACHINES CORPORATION

(21) Appl. No.: 13/189,855

(22) Filed: Jul. 25, 2011

(51) Int. Cl. H05K 7/20

(52) U.S. Cl. 361/702

(57) ABSTRACT

A multi-chip electronic module includes a circuit board having a first end portion, a second end portion, a first surface portion and an opposing second surface portion. A plurality of electronic components is mounted to the first surface portion of the circuit board. A heat spreader member is supported at the first surface portion of the circuit board. The heat spreader includes a body having a first end, a second end, a first surface and a second surface. The first end portion and first end define a fluid inlet, and the second end portion and second end define a fluid outlet. The second surface is in thermal contact with the plurality of electronic components. The heat spreader member and circuit board define an enclosed fluid duct having a plurality of substantially parallel flow paths.

### BACKGROUND

The present invention relates to the art of electronic systems and, and more specifically, to a heat spreader for electronic systems including multi-chip modules.

Electronic devices are being designed to conform to smaller and smaller packages. Arranging an ever increasing number of electronic components into ever decreasing packages presents various challenges including heat dissipation. In addition to cooling the electronic components, heat must also be removed from power generation devices. At present, most electronic devices are coupled to heat sinks that facilitate heat dissipation. Power generation devices are generally coupled to fans. In addition to cooling the power generation device, often times the fan are arranged so as to draw air across the electronic components to further facilitate heat dissipation.

### SUMMARY

According to one embodiment of the present invention, a multi-chip electronic module includes a circuit board having a first end portion, a second end portion, a first surface portion and an opposing second surface portion. A plurality of electronic components is mounted to the first surface portion of the circuit board. A heat spreader member is supported at the first surface portion of the circuit board. The heat spreader includes a body having a first end, a second end, a first surface and a second surface. The first end portion and first end define a fluid inlet, and the second end portion and second end define a fluid outlet. The second surface is in thermal contact with the plurality of electronic components. The heat spreader member and circuit board define an enclosed fluid duct having a plurality of substantially parallel flow paths.

According to another embodiment of the present invention, a method of cooling a multi-chip electronic module includes receiving in an inlet of the multi-chip module an amount of fluid, and passing the amount of fluid along a plurality of substantially parallel flow paths that extends between a heat spreader member and a printed circuit board supporting a plurality of electronic components. The plurality of electronic components is in thermal contact with an internal surface of the heat spreader member. A heat exchange is facilitated between the plurality of electronic components and the amount of fluid passing along the flow path.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a perspective view of a multi-chip electronic module in accordance with an exemplary embodiment;

FIG. 2 is a partial cross-sectional elevational side view of the multi-chip electronic module of FIG. 1;

FIG. 3 is a partial cross-sectional elevational end view of the multi-chip module of FIG. 1; and

FIG. 4 is a plan view of the multi-chip electronic module of FIG. 1

### DETAILED DESCRIPTION

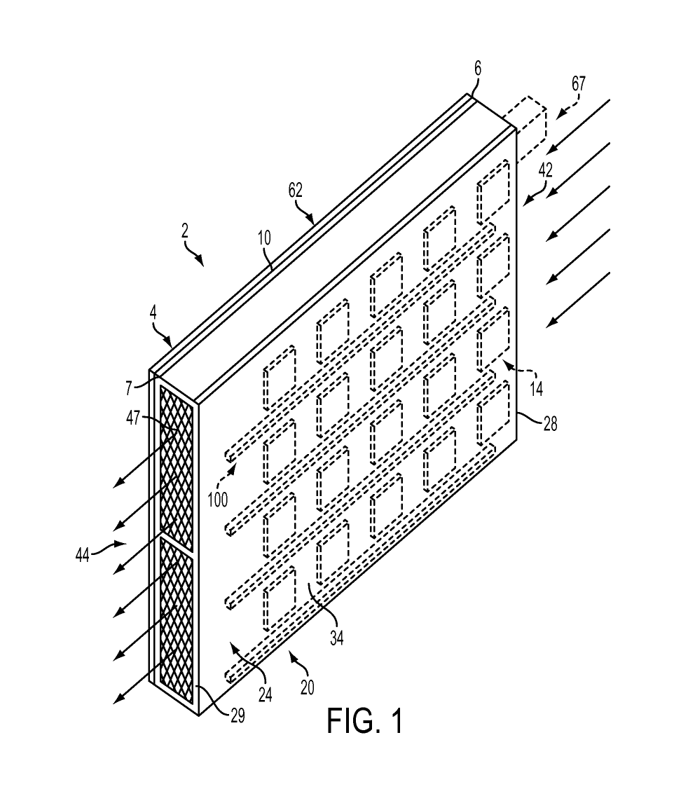

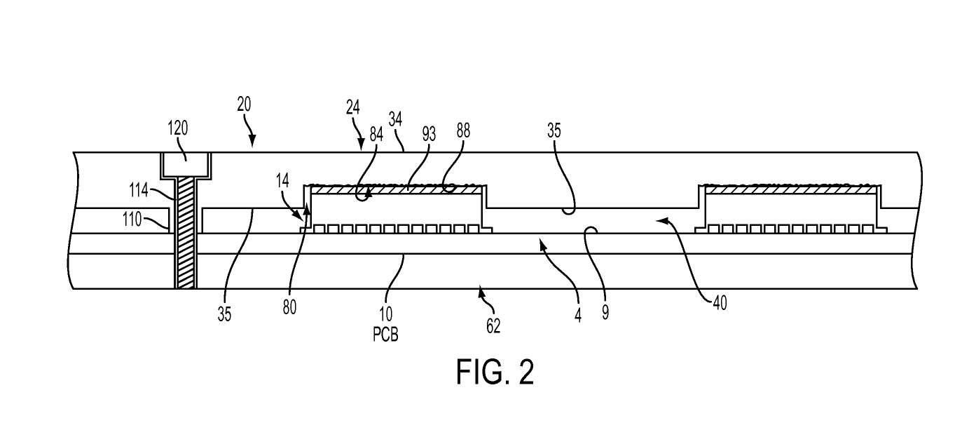

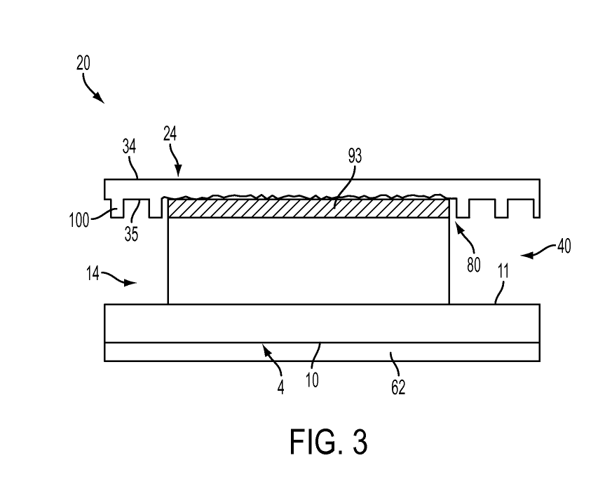

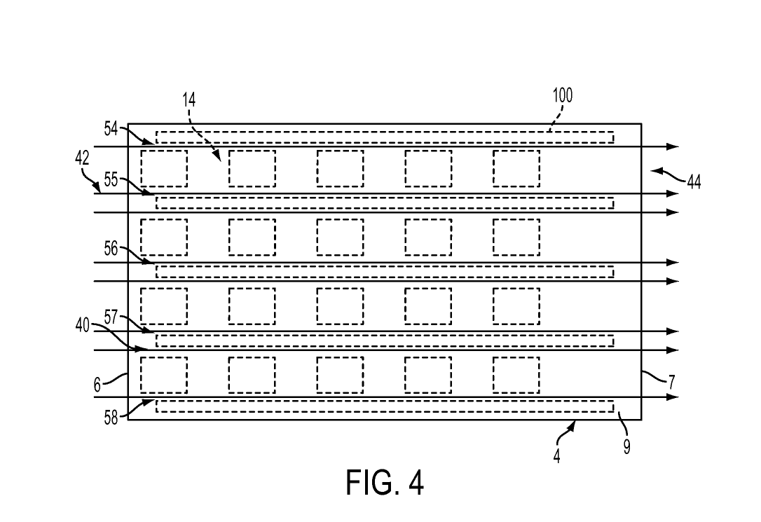

With reference now to FIGS. 1-4, a multi-chip electronic module in accordance with an exemplary embodiment is indicated generally at 2. Multi-chip electronic module 2 includes a circuit board 4 having a first end portion 6 that extends to a second end portion 7. Circuit board 4 also includes a first surface portion 9 and an opposing second surface portion 10. A plurality of electronic components, one of which is indicated at 14, are mounted to first surface portion 9 of circuit board 4. The number, type, and particular arrangement of electronic components can vary. In the exemplary embodiment shown, electronic components 14 take the form of circuit chips.

In accordance with the exemplary embodiment shown, multi-chip module 2 includes a heat spreader member 20 supported above first surface portion 9 of circuit board 4. Heat spreader member 20 includes a body 24 having a first end 28 that extends to a second end 29. In the exemplary embodiment shown, body 24 is formed from aluminum, however it should be understood that other heat conducting materials could also be employed. Body 24 also includes a first surface 34 and a second surface 35. Although shown extending seamlessly between first and second ends 28 and 29, it should be understood that body 24 could be formed in multiple pieces. Heat spreader member 20 and circuit board 4 cooperate for form an enclosed fluid duct 40. Fluid duct 40 is defined by first surface portion 9 of circuit board 4 and second surface 35 of heat spreader member 20. Fluid duct 40 includes a fluid inlet defined by first end portion 6 and first end 28 and a fluid outlet 44 defined by second end portion 7 and second end 29. Multi-chip electronic module 2 is shown to include an outlet screen 47 arranged at fluid outlet 44. It should be understood that multi-chip module 2 may include an inlet screen (not shown) at fluid inlet 42. Outlet screen 47 and or an inlet screen (not shown) may be used individually or in combination. Fluid duct 40 includes a plurality of parallel flow paths 54-58 that extend between fluid inlet 42 and fluid outlet 44. Multi-chip electronic module 2 is further shown to include a stiffener member 62 that extends over second surface portion 10 of circuit board 4 and a connector 67 arranged at fluid inlet 42. As will be discussed more fully below, stiffener member 62 is mechanically linked to heat spreader member 20 to minimize strain in circuit board 4 and, by extension, on connections between circuit board 4 and electronic components 14.

In further accordance with an exemplary embodiment, heat spreader member 20 includes a plurality of cavities, one of which is indicated at 80, formed in second surface 35. Cavities 80 are configured to receive corresponding ones of electronic components 14. As such, cavity size, depth, and geometry may vary depending on the particular electronic components 14 employed. Each cavity 80 includes at least one thermal interface surface 84 formed in second surface 35 that is in thermal contact with a surface (not separately labeled) of electronic component 14. In the exemplary embodiment shown, thermal interface surface 84 includes a surface treatment 88 such as roughening, grooves, projections and the like. Surface treatment 88 limits any excursion of a thermal interface material (TIM) 93 arranged between electronic component 14 and thermal interface surface 84. TIM 93 facilitates thermal transfer between electronic component 14 and heat spreader member 20.

Heat spreader member 20 is further shown to include a plurality of fin elements, one of which is indicated at 100 that extend from second surface 35. Fin elements enhance heat exchange between fluid flowing through fluid duct 40 and heat spreader member 20. The number, length, width, and depth of fin elements 100 can vary. In addition, heat spreader member 20 includes a plurality of mounting elements 110 that extend from second surface 35. Mounting elements 110 provide a mechanical link between heat spreader member 20 and circuit board 4. More specifically, when heat spreader member 20 is positioned upon circuit board 4, mounting elements 110 abut first surface portion 9 so as to define a thermal interface gap (not seperately labeled). Each mounting element 110 includes a central passage 114 that is configured to receive a mechanical fastener 120. In the exemplary embodiment shown, mechanical fastener 120 extends into and engages with stiffener member 62. However, it should be understood, that mechanical fastener 120 could also extend through stiffener member 62 and be provided with, for example a nut. Alternatively, mechanical fastener 120 could terminate within circuit board 4.

At this point it should be understood that the exemplary embodiments provide a multi-chip electronic module having a heat spreader member that defines a fluid duct configured to receive a fluid, such as air, that is passed in a convective heat exchange relationship with electronic components mounted to a circuit board. The fluid can be supplied by a fan directly mounted to the multi-chip electronic module, or be linked to the fluid inlet via ducting. In addition to exchanging heat with the fluid, the electronic components exchange heat conductively with the heat spreader member in order to further lower localized temperatures. The combination of convective and conductive heat exchange enables the multi-chip module to support a wide array of electronic components including both power generating and power consuming devices.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. A multi-chip electronic module comprising:
a circuit board including a first end portion, a second end portion, a first surface portion and an opposing second surface portion;
a plurality of electronic components mounted to the first surface portion of the circuit board;
a heat spreader member supported at the first surface portion of the circuit board, the heat spreader including a body having a first end, a second end, a first surface and a second surface, the first end portion and first end defining a fluid inlet and the second end portion and second end defining a fluid outlet, the second surface being in thermal contact with the plurality of electronic components, the heat spreader member and circuit board defining an enclosed fluid duct having a plurality of substantially parallel flow paths.

2. The multi-chip electronic module according to claim 2, wherein the heat spreader member includes a plurality of cavities formed in the second surface, the plurality of cavities being configured and disposed to receive corresponding ones of the plurality of electronic components.

3. The multi-chip module according to claim 2, wherein each of the plurality of cavities includes a thermal interface surface and a thermal interface material arranged between the thermal interface surface and the corresponding one of the plurality of electronic components.

4. The multi-chip module according to claim 3, wherein the thermal interface surface includes a surface treatment configured and disposed to limit migration of the thermal interface material.

5. The multi-chip module according to claim 1, further comprising: a thermal interface material arranged between the second surface of the heat spreader member and a corresponding one of the plurality of electronic components.

6. The multi-chip module according to claim 1, further comprising: a plurality of fin elements extending from the second surface of the heat spreader member toward the circuit board.

7. The multi-chip module according to claim 1, further comprising: a stiffener member arranged on the second surface portion of the circuit board.

8. The multi-chip module according to claim 7, further comprising at least one mounting element extending from the second surface of the heat spreader member toward the circuit board, the mounting element abutting that first surface portion of the circuit board and includes a central passage.

9. The multi-chip module according to claim 8, further comprising: a mechanical fastener extending through the central passage of the at least one mounting element into the stiffener member.

10. The multi-chip module according to claim 1, further comprising: one of an inlet screen arranged at the fluid inlet and an outlet screen arranged at the fluid outlet.

11-20. (canceled)
